(19) United States
(12) Patent Application Publication
(10) Pub. No.: US 2026/0250184 A1
(43) Pub. Date: Aug. 27, 2026

(54) Method For Manufacturing A Window

(71) Applicant: Samsung Display Co., Ltd., Yongin-si (KR)

(72) Inventors: Jaegil Lee, Yongin-si (KR); Byeong-Beom Kim, Yongin-si (KR); Byeong-Su Kim, Yongin-si (KR); Seungho Kim, Yongin-si (KR); Jinsu Nam, Yongin-si (KR); Junho Lee, Yongin-si (KR); Min-Hoon Choi, Yongin-si (KR)

(73) Assignee: Samsung Display Co., Ltd., Yongin-si (KR)

(21) Appl. No.: 19/355,230

(22) Filed: Oct. 10, 2025

(30) Foreign Application Priority Data
Feb. 26, 2025 (KR) 10-2025-0025145

(51) Int. Cl. C03C 15/00; H05K 5/03

(52) U.S. Cl. CPC C03C 15/00; H05K 5/03

(57) ABSTRACT

A method for manufacturing a window may include providing a preliminary substrate including a base substrate, adhesive layers, and protective films, forming a recess by etching the portion of the upper surface, irradiating the lower surface with UV, gradually removing the first adhesive layer and the first protective film by using a roller disposed on the preliminary substrate, and forming inclined portions by etching the base substrate, wherein gradually removing a protective film and an adhesive layer disposed on the base substrate and the forming of the inclined portions are simultaneously performed.

### CROSS-REFERENCE TO RELATED APPLICATIONS

This U.S. non-provisional patent application claims priority under 35 U.S.C. § 119 to Korean Patent Application No. 10-2025-0025145, filed on February 26, 2025, the entire contents of which are hereby incorporated by reference.

### TECHNICAL FIELD

The present disclosure relates to a method for manufacturing a window included in a foldable electronic device.

### BACKGROUND

Various electronic devices such as a television, a mobile phone, a tablet computer, and a game console are being developed. Flexible electronic devices including a flexible display panel which is slidable or foldable are recently being developed. Unlike a rigid electronic device, a flexible electronic device may be foldable, rollable, or bendable. The flexible electronic device having a shape that is variously changeable may be carried regardless of the existing screen size thereof, and thus user convenience is improved. It is required for a window included in the flexible electronic device to have improved folding characteristics in a folding region.

### SUMMARY

The present disclosure provides a method for manufacturing a window with improved folding characteristics in a folding region.

An aspect of the present disclosure provides a method for manufacturing a window including providing a preliminary substrate in which a first adhesive layer and a first protective film are disposed on an upper surface of a base substrate, and a second adhesive layer and a second protective film are disposed on a lower surface of the base substrate, forming an opening by removing the first adhesive layer and the first protective film so that a portion of the upper surface is exposed, arranging a guide portion surrounding at least a portion of the preliminary substrate, forming a recess by etching the portion of the upper surface, irradiating the lower surface with ultraviolet (UV), gradually removing the first adhesive layer and the first protective film by using a roller disposed on the preliminary substrate, and forming inclined portions by etching a region, in which the first adhesive layer and the first protective film are removed, of the base substrate, wherein the gradually removing of the first adhesive layer and the first protective film and the forming of the inclined portions are simultaneously performed.

In an aspect, an external angle between an extension line parallel to the upper surface of the base substrate defining the recess and each of side surfaces of the base substrate defining the inclined portions may increase as the roller is moved faster.

In an aspect, the external angle may be about 0.01 degrees to about 1 degree.

In an aspect, the method for manufacturing a window may further include removing the guide portion from the preliminary substrate after the forming of the inclined portions.

In an aspect, the method for manufacturing a window may further include removing the first and second adhesive layers and the first and second protective films from the base substrate.

In an aspect, the method for manufacturing a window may further include blanket etching the upper surface and the lower surface of the base substrate after the removing of the first and second adhesive layers and the first and second protective films.

In an aspect, the inclined portions, a flat portion disposed between the inclined portions, and non-folding portions connected to respective ends of the inclined portions may be formed in the base substrate after the blanket etching.

In an aspect, a thickness of the non-folding portions may be greater than a thickness of the flat portion.

In an aspect, the thickness of the non-folding portions may be about 50 um to about 300 um, and the thickness of the flat portion may be about 20 um to about 100 um.

In an aspect, the base substrate may include glass.

In an aspect, the first adhesive layer and the second adhesive layer may include pressure sensitive adhesives (PSAs) having different characteristics.

In an aspect, the first adhesive layer may include a UV photosensitive pressure sensitive adhesive, and the second adhesive layer may include a thermal pressure sensitive adhesive.

In an aspect, the first protective film and the second protective film may include at least one of polyolefin (PO), polyethylene (PE), polyethylene terephthalate (PET), or polyvinyl chloride (PVC).

In an aspect, after the forming of the recess, the first adhesive layer may be divided into a first adhesive portion and a second adhesive portion spaced apart from each other with the recess therebetween, and the first protective film may be divided into a first film portion disposed on the first adhesive portion and a second film portion disposed on the second adhesive portion, the first film portion and the second film portion being spaced apart from each other with the recess therebetween.

In an aspect, the roller may include a first roller disposed on the first film portion and a second roller disposed on the second film portion, an end of the first film portion and an end of the first adhesive portion adjacent to the recess may be wound by the first roller, and an end of the second film portion and an end of the second adhesive portion adjacent to the recess may be wound by the second roller.

In an aspect, in the gradually removing of the first adhesive layer and the first protective film, the first roller and the second roller may gradually move away from each other in directions from a center of the base substrate to outer sides of the base substrate.

In an aspect, in the gradually removing of the first adhesive layer and the first protective film, as the first roller and the second roller move away from each other, the base substrate may be gradually exposed while the (1-1)-th adhesive layer and the (1-1)-th film portion are being wound on the first roller due to lost adhesive force of the (1-1)-th adhesive layer irradiated with the UV, and the base substrate may be gradually exposed while the (1-2)-th adhesive layer and the (1-2)-th film portion are being wound on the second roller due to lost adhesive force of the (1-2)-th adhesive layer irradiated with the UV.

In an aspect, when the first roller and the second roller move away from each other, the guide portion may be moved to expose the base substrate.

In an aspect, the guide portion may expose an upper surface and a lower surface of the base substrate overlapping the recess.

In an aspect, the guide portion may expose one side of the base substrate extending along the same direction as a direction in which the recess extends, and cover another side of the base substrate extending in a direction crossing a direction in which the one side extends.

### BRIEF DESCRIPTION OF THE FIGURES

The accompanying drawings are included to provide a further understanding of the present disclosure, and are incorporated in and constitute a part of this specification. The drawings illustrate aspects of the present disclosure and, together with the description, serve to explain principles of the present disclosure. In the drawings:

FIG. 1A is a block diagram of an electronic device according to an aspect;

FIG. 1B is a schematic view of electronic devices according to various aspects;

FIG. 2A is a perspective view illustrating an electronic device of an aspect;

FIG. 2B is a perspective view illustrating an electronic device of an aspect;

FIG. 2C is a perspective view illustrating an electronic device of an aspect;

FIG. 2D is a perspective view illustrating an electronic device of an aspect;

FIG. 2E is a perspective view illustrating an electronic device according to an aspect;

FIG. 2F is a perspective view illustrating an electronic device according to an aspect;

FIG. 2G is a perspective view illustrating an electronic device according to an aspect;

FIG. 3 is an exploded perspective view illustrating an electronic device of an aspect;

FIG. 4 is a cross-sectional view taken along I-I' of FIG. 3;

FIG. 5 is a cross-sectional view of a window according to an aspect of the present disclosure; and

FIGS. 6 to 11B are diagrams illustrating sequential steps of a method for manufacturing a window according to an aspect of the present disclosure.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concept. Similarly, a second element could be termed a first element. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of the present disclosure are described with reference to the drawings.

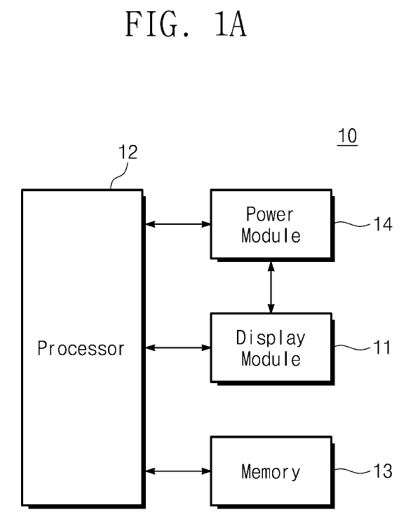

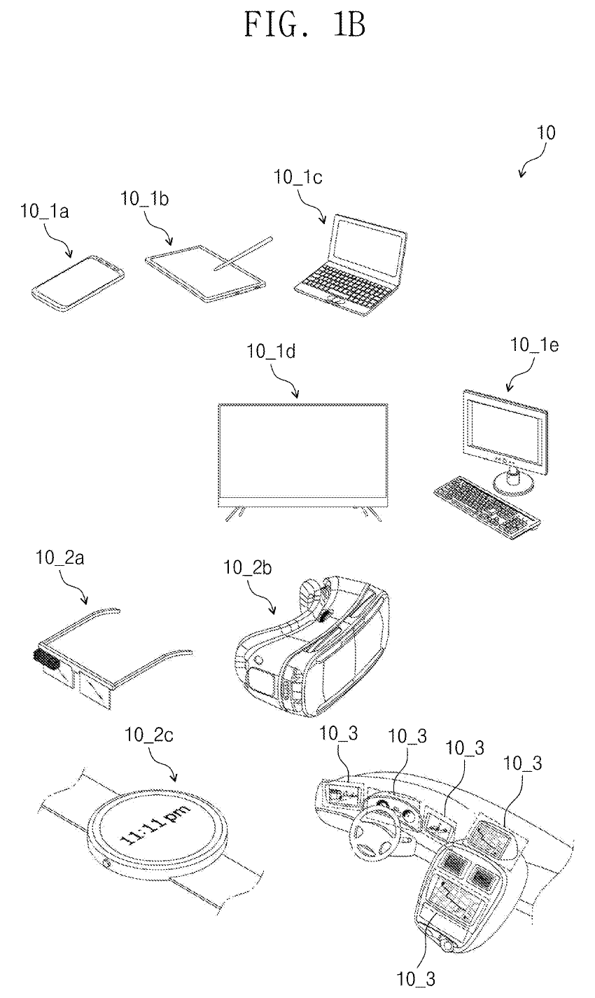

FIG. 1A is a block diagram of an electronic device according to an aspect. FIG. 1B is a schematic view of electronic devices according to various aspects.

Referring to FIG. 1A, an electronic device 10 according to an aspect may include a display module 11, a processor 12, a memory 13, and a power module 14.

The processor 12 may include at least one among a central processing unit (CPU), an application processor (AP), a graphic processing unit (GPU), a communication processor (CP), an image signal processor (ISP), and a controller.

Data information required for an operation of the display module 11 or the processor 12 may be stored in the memory 13. When the processor 12 executes an application stored in the memory 13, an image data signal and/or an input control signal may be transferred to the display module 11, and the display module 11 may process the provided signal and output image information through a display screen.

The power module 14 may include a power supply module such as a power adaptor or a battery device and a power conversion module which converts power supplied by the power supply module and generates power required for an operation of the electronic device 10.

At least one of the components of the electronic device 10 described above may be included in an electronic device according to the aspects described above. In addition, some of individual modules included functionally in one module may be included in the electronic device, and the others thereof may be provided separately from the electronic device. For example, the electronic device may include the display module 11, and the processor 12, the memory 13, and the power module 14 may be provided in a form of another device, in the electronic device 10, other than the electronic device.

Referring to FIG. 1B, various electronic devices to which the electronic device according to an aspect of the present disclosure is applied may include not only an electronic device for displaying an image, such as a smartphone 10_1a, a tablet PC 10_1b, a laptop 10_1c, a TV 10_1d, or a desk monitor 10_1e, but also a wearable electronic device including a display module, such as smart glasses 10_2a, a head-mounted display 10_2b, or a smart watch 10_2c, automotive electronic devices 10_3 including a display module, such as a center information display (CID) disposed on an instrument panel, a center fascia, or a dashboard of an automobile or a room mirror display, etc.

The electronic device according to an aspect may be applied to various electronic devices. The electronic device according to an aspect may include the electronic device described above, and may further include a module or device having another additional function in addition to the electronic device. Hereinafter, a foldable electronic device among the electronic devices described above will be described as an example, and a window which is formed using a method for manufacturing a window to be described below may be applied to the foldable electronic device.

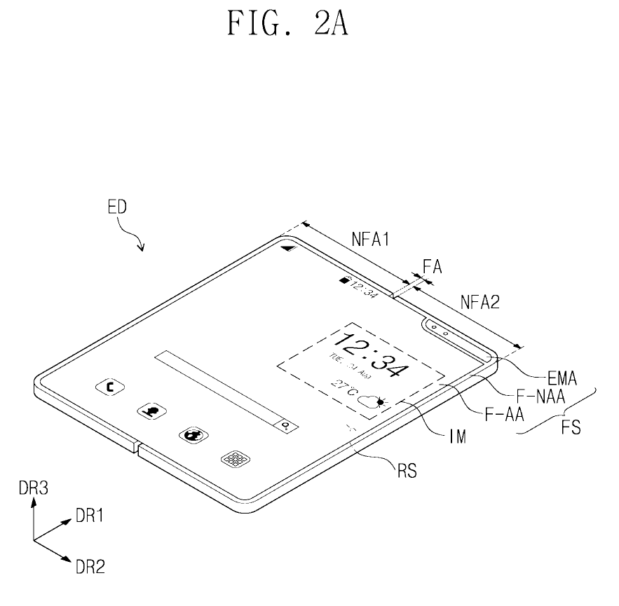

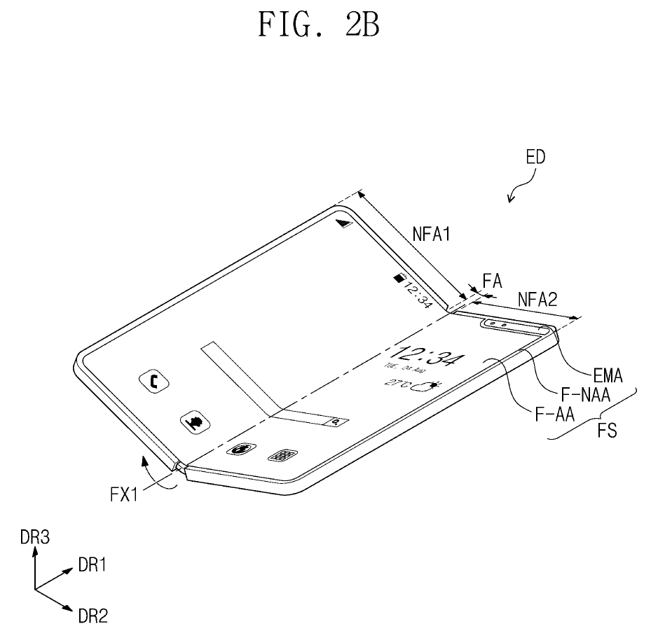

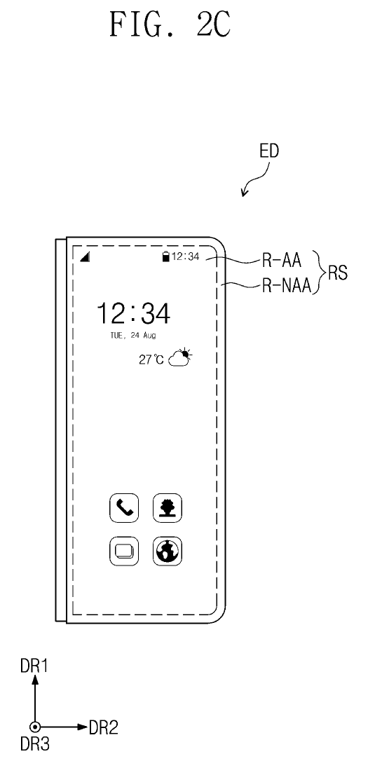

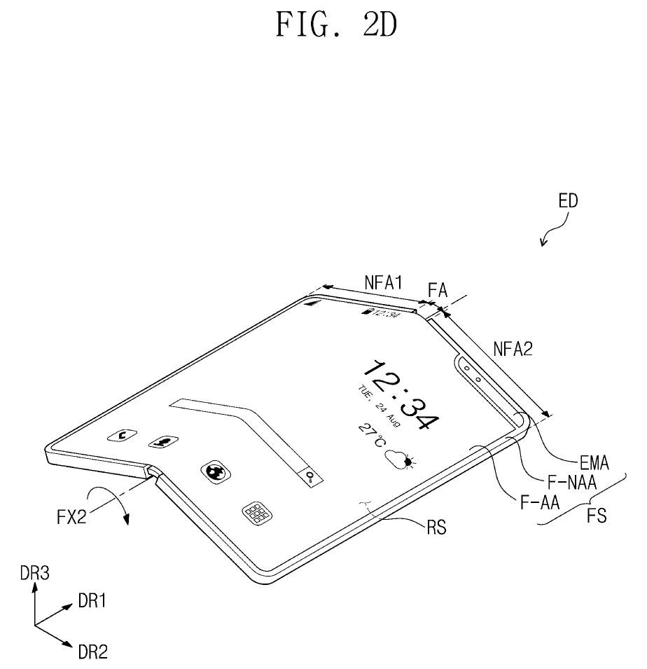

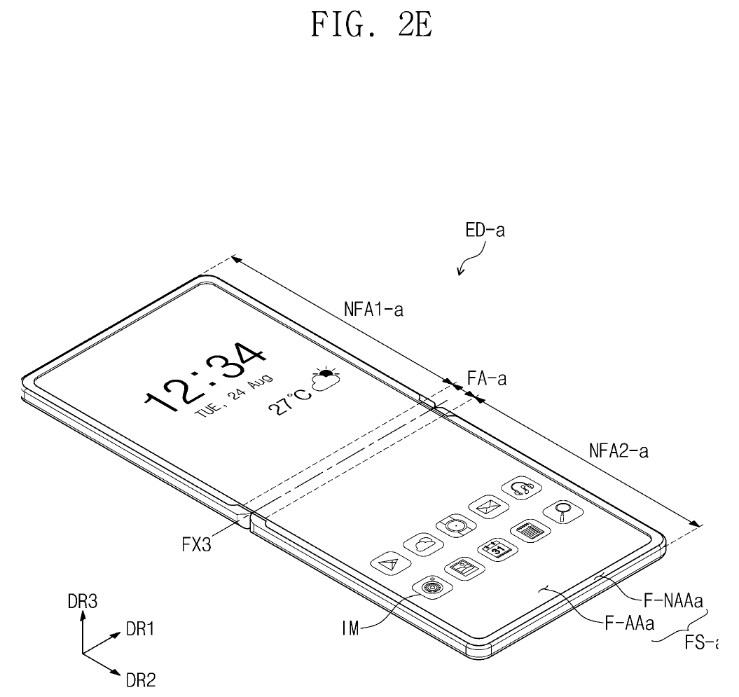

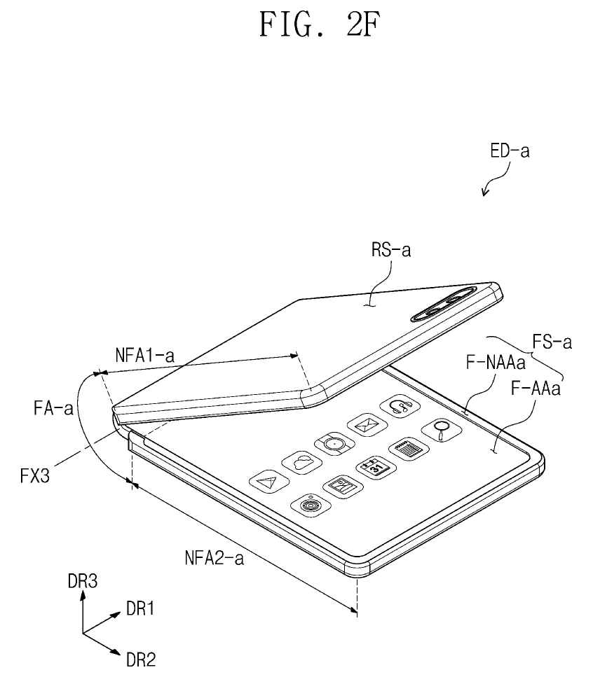

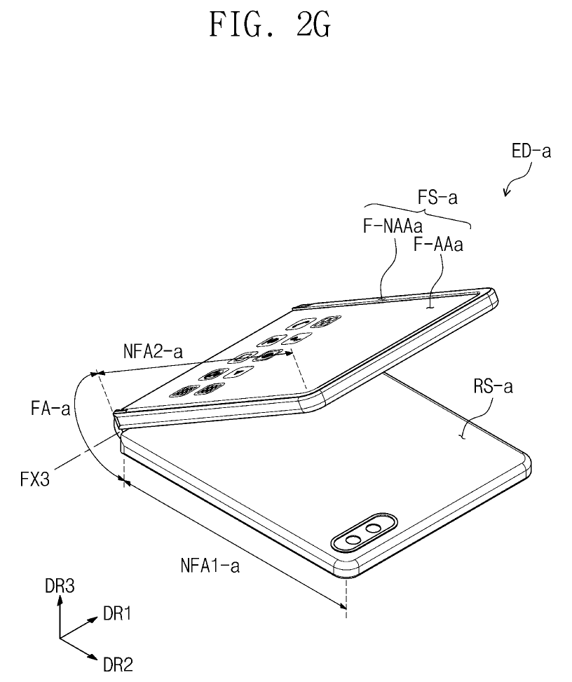

FIGS. 2A to 2D are perspective views illustrating an electronic device of an aspect of the present disclosure.

FIG. 2A is a perspective view of an unfolded state of an electronic device ED according to an aspect. The electronic device ED of an aspect of the present disclosure may be activated in response to an electrical signal. For example, the electronic device ED may be a mobile phone, a tablet PC, a car navigation unit, a game console, or a wearable device, but aspects of the present disclosure are not limited thereto. FIGS. 2A to 2G illustrate foldable electronic devices ED and ED-a among the electronic devices described above as an example. The foldable electronic devices ED and ED-a according to an aspect may be mobile devices.

The electronic device ED may include a first display surface FS defined by a first direction DR1 and a second direction DR2 crossing the first direction DR1. The electronic device ED may provide an image IM to a user through the first display surface FS. The electronic device ED may display the image IM in a third direction DR3 through the first display surface FS parallel to each of the first direction DR1 and the second direction DR2.

In this specification, the first direction DR1 and the second direction DR2 may be perpendicular to each other, and the third direction DR3 may be a normal direction with respect to a plane defined by the first direction DR1 and the second direction DR2. A thickness direction of the electronic device ED may be a direction parallel to the third direction DR3.

A front surface (or an upper surface) and a rear surface (or a lower surface) may be opposed to each other in the third direction DR3, and a normal direction of each of the front surface (or upper surface) and the rear surface (or lower surface) may be parallel to the third direction DR3. The front surface (or upper surface) means a surface close to the first display surface FS, and the rear surface (or lower surface) means a surface spaced apart from the first display surface FS. In addition, the rear surface (or lower surface) means a surface close to a second display surface RS to be described later. An upper side (or an upper portion) means a direction to the first display surface FS, and a lower side (or a lower portion) means a direction getting farther away from the first display surface FS.

A cross section of elements means a surface parallel to the third direction DR3 which is a thickness direction, and a plane means a surface perpendicular to the third direction DR3 which is a thickness direction. The plane means a surface defined by the first direction DR1 and the second direction DR2.

The electronic device ED may sense an external input applied from the outside. The external input may include inputs in various forms provided from an outside of the electronic device ED. For example, the external input may include not only a contact from part of a body, such as a user’s hand, but also an external input (for example, hovering) approaching the electronic device ED or adjacently applied to the electronic device ED at a predetermined distance. In addition, the external input may have various forms such as force, pressure, temperature, and light.

The electronic device ED may include the first display surface FS and a second display surface RS. The first display surface FS may include a first active region F-AA, a first peripheral region F-NAA, and an electronic module region EMA. The second display surface RS may be defined as an opposing surface of first display surface FS. That is, the second display surface RS may be defined as a portion of a rear surface of the electronic device ED.

The first active region F-AA may be a region activated in response to an electrical signal. The first active region F-AA may be a region in which the image IM may be displayed and an external input in various forms may be sensed.

The first peripheral region F-NAA may be a region in which the image IM is not displayed. The first peripheral region F-NAA may be adjacent to the first active region F-AA. The first peripheral region F-NAA may have a predetermined color. The first peripheral region F-NAA may surround the first active region F-AA. Accordingly, a shape of the first active region F-AA may be substantially defined by the first peripheral region F-NAA. However, this is an example, and the first peripheral region F-NAA may be disposed adjacent to only one side of the first active region F-AA or may be omitted.

Various electronic modules may be disposed in the electronic module region EMA. For example, an electronic module may include at least one among a camera, a speaker, an optical sensor, and a thermal sensor. The electronic module region EMA may sense an external subject which is received through the display surfaces FS and RS or may provide a sound signal such as voice to the outside through the display surfaces FS and RS. The electronic module may include a plurality of components and is not limited to any one aspect.

The electronic module region EMA may be surrounded by the first peripheral region F-NAA. However, this is an example, and the electronic module region EMA is not limited to any one aspect. For example, the electronic module region EMA may be surrounded by the first active region F-AA and the first peripheral region F-NAA, and the electronic module region EMA may be disposed in the first active region F-AA.

The electronic device ED according to an aspect may be divided into at least one folding region FA and a plurality of non-folding regions NFA1 and NFA2 extending from the folding region FA. For example, a first non-folding region NFA1, a folding region FA, and a second non-folding region NFAB may be defined along the second direction DR2. The electronic device ED may be divided into the first non-folding region NFA1 and the second non-folding region NFA2 spaced apart from each other in the second direction DR2 with the folding region FA therebetween. For example, the first non-folding region NFA1 may be disposed on one side of the folding region FA in the second direction DR2, and the second non-folding region NFA2 may be disposed on the other side of the folding region FA in the second direction DR2.

FIG. 2A illustrates an aspect of the electronic device ED including one folding region FA, but aspects of the present disclosure are not limited thereto, and a plurality of folding regions may be defined in the electronic device ED. For example, the electronic device according to an aspect may include two or more folding regions and three or more non-folding regions disposed with each of the folding regions therebetween.

FIG. 2B is a perspective view illustrating a folding operation of the electronic device ED according to an aspect. FIG. 2C is a plan view of a folded state of the electronic device ED according to an aspect. FIG. 2D is a perspective view illustrating a folding operation of the electronic device ED according to an aspect.

Referring to FIG. 2B, the electronic device ED according to an aspect may be folded with respect to a first folding axis FX1 extending in the first direction DR1. The folding region FA may have predetermined curvature and radius of curvature in a state in which the electronic device ED is folded. The electronic device ED may be folded with respect to the first folding axis FX1 and changed into an in-folding state so that the first non-folding region NFA1 and the second non-folding region NFA2 face each other and the first display surface FS is not exposed to the outside.

Referring to FIG. 2C, the second display surface RS may be viewed by a user in the in-folding state of the electronic device ED according to an aspect. In this case, the second display surface RS may include a second active region R-AA in which an image is displayed. The second active region R-AA may be a region activated in response to an electrical signal. The second active region R-AA may be a region in which an image may be displayed and an external input in various forms may be sensed.

In addition, the second display surface RS may include a second peripheral region R-NAA. The second peripheral region R-NAA may be adjacent to the second active region R-AA. The second peripheral region R-NAA may have a predetermined color. The second peripheral region R-NAA may surround the second active region R-AA. In addition, although not illustrated, the electronic device ED may further include, in the second display surface RS as well, an electronic module region in which an electronic module including various components is disposed, and is not limited to any one aspect.

According to an aspect, in a state in which the electronic device ED is in-folded, a distance between the first non-folding region NFA1 and the second non-folding region NFA2 may be smaller than a radius of a circle defined by a radius of curvature of the folding region FA. In this case, the folding region FA may be folded in a dumbbell shape, and the distance between the first non-folding region NFA1 and the second non-folding region NFA2 may be further shortened. Thus, the electronic device ED which is slimmer in a folding state may be provided.

Referring to FIG. 2D, the electronic device ED according to an aspect may be folded with respect to a second folding axis FX2 extending in the first direction DR1. The electronic device ED may be folded with respect to the second folding axis FX2 and changed into an out-folding state so that the first display surface FS is exposed to the outside. In an aspect, the electronic device ED may be configured so that an unfolding operation and an in-folding or out-folding operation are repeated, but is not limited thereto.

FIGS. 2A to 2D illustrate, as an example, that the electronic device ED is folded with respect to one folding axis FX1 or FX2, but the number of folding axes and the number of non-folding regions according to the number of folding axes are not limited thereto. For example, the electronic device ED may be folded with respect to a plurality of folding axes so that respective portions of the first display surface FS and second display surface RS face each other. In addition, it is illustrated that the first and second folding axes FX1 and FX2 are parallel to a long side of the electronic device ED, but aspects of the present disclosure are not limited thereto, and the first and second folding axes FX1 and FX2 may be parallel to a short side of the electronic device ED.

In the electronic device ED, the first non-folding region NFA1 and the second non-folding region NFA2 may be defined as portions having the display surfaces FS and RS parallel to a plane defined by the first direction DR1 and the second direction DR2 in a folded state as illustrated in FIG. 2C, and the folding region FA may be defined as a region between the first non-folding region NFA1 and the second non-folding region NFA2. The folding region FA may include a curved portion bent so as to have a predetermined curvature in a folded state.

FIGS. 2E to 2G are perspective views illustrating an electronic device according to another aspect. FIGS. 2E to 2G are perspective views illustrating the electronic device ED-a according to another aspect of the present disclosure. FIG. 2E is a perspective view illustrating an unfolded state of the electronic device ED-a. FIGS. 2F and 2G are perspective views illustrating a folding operation of the electronic device ED-a. FIG. 2F is a perspective view illustrating an in-folding operation of the electronic device ED-a illustrated in FIG. 2E. FIG. 2G is a perspective view illustrating an out-folding operation of the electronic device ED-a illustrated in FIG. 2E.

Referring to FIG. 2E, the electronic device ED-a may be folded with respect to a third folding axis FX3 extending along a first direction DR1. An extension direction of the third folding axis FX3 may be parallel to an extension direction of a short side of the electronic device ED-a.

The electronic device ED-a may be divided into a folding region FA-a, a first non-folding region NFA1-a adjacent to one side of the folding region FA-a, and a second non-folding region NFA2-a adjacent to another side of the folding region FA-a. The first non-folding region NFA1-a and the second non-folding region NFA2-a may be spaced apart from each other with the folding region FA-a therebetween.

The folding region FA-a may be a region folded with respect to the third folding axis FX3. The folding region FA-a may have a predetermined curvature and radius of curvature in a state in which the electronic device ED-a is folded. The electronic device ED-a may be in-folded so that the first non-folding region NFA1-a and the second non-folding region NFA2-a face each other and a display surface FS-a is not exposed to the outside.

Referring to FIG. 2E, in an aspect, a display surface FS-a may be viewed by a user in an unfolded state (that is, a state in which the electronic device ED-a is not folded) of the electronic device ED-a. As described with reference to FIGS. 2A to 2D, the display surface FS-a of the electronic device ED-a may include an active region F-AAa and a peripheral region F-NAAa. The active region F-AAa may be a region in which an image IM may be displayed and an external input in various forms may be sensed.

Referring to FIG. 2F, a rear surface RS-a may be viewed by a user in a state in which the electronic device ED-a of an aspect is folded. For example, the rear surface RS-a may function as a second display surface which displays an image. In addition, an electronic module region in which an electronic module including various components is disposed may be disposed on the rear surface RS-a as well. According to an aspect, an active region in which an image is displayed may be further included in the rear surface RS-a of the electronic device ED-a.

Referring to FIG. 2G, the electronic device ED-a may be folded with respect to the third folding axis FX3 and changed into an out-folding state in which one region overlapping the first non-folding region NFA1-a and another region overlapping the second non-folding region NFA2-a of the rear surface RS-a face each other.

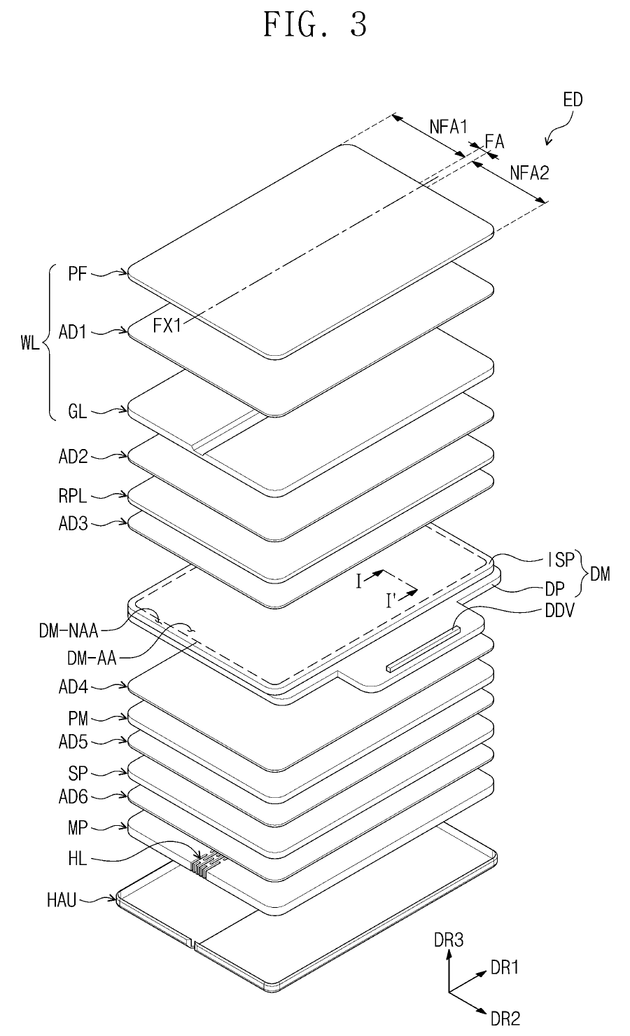

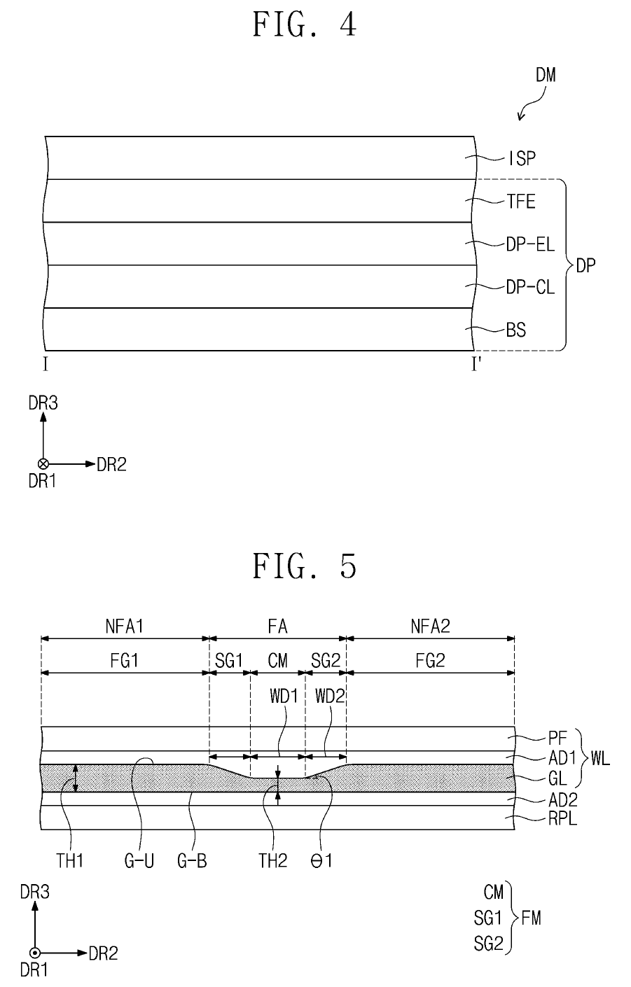

FIG. 3 is an exploded perspective view illustrating an electronic device of an aspect. FIG. 4 is a cross-sectional view taken along I-I' of FIG. 3.

Referring to FIG. 3, an electronic device ED may include a window WL, an optical layer RPL, a display module DM, a lower film PM, a support plate SP, a lower plate MP, and a housing HAU.

The housing HAU may be coupled to the window WL and define an exterior of the electronic device ED. The housing HAU may include a material having relatively high rigidity. For example, the housing HAU may include a plurality of frames and/or support plates including glass, plastic or metal.

The housing HAU may provide a predetermined accommodation space. The display module DM may be accommodated in the accommodation space and protected from an external impact. According to an aspect, the housing HAU overlapping a folding region FA may further include a hinge structure for guiding a folding operation of the electronic device ED, etc.

The display module DM may be disposed on a lower portion of the optical layer RPL. The display module DM may be activated in response to an electrical signal. The display module DM may be activated and display the image IM (see FIG. 2A) in the active region F-AA (see FIG. 2A) of the electronic device ED. A display region DM-AA and a non-display region DM-NAA may be defined on the display module DM. The display region DM-AA may be a region activated in response to an electrical signal. The non-display region DM-NAA may be a region located adjacent to at least one side of the display region DM-AA. A circuit, a line, or the like for driving the display region DM-AA may be disposed in the non-display region DM-NAA.

The display module DM may include a display panel DP including pixels providing an image and an input sensing layer ISP disposed on the display panel DP. A data driver DDV which drives the pixels may be mounted on the display panel DP overlapping the non-display region DM-NAA.

The optical layer RPL may be disposed between the display module DM and the window WL. The optical layer RPL may be an anti-reflective layer which reduces reflectance for external light incident from an outside of the display module DM. The optical layer RPL may be formed on the display module DM through a continuous process. The optical layer RPL may include a polarizing plate or a color filter layer. For example, the optical layer RPL may include at least one of a retarder, a polarizer, a polarizing film, or a polarizing filter. Alternatively, the optical layer RPL may include a plurality of color filters disposed in a predetermined arrangement and a black matrix adjacent to the color filters.

The image IM (see FIG. 2A) generated in the display module DM may transmit through the window WL and may be provided to a user. The window WL may include a polymer substrate or a glass substrate.

The window WL according to an aspect may include a protective layer PF and a base substrate GL including glass. The protective layer PF and the base substrate GL may include an optically transparent insulating material.

The protective layer PF may be disposed on the base substrate GL. The protective layer PF may be a functional layer which protects an upper surface of the base substrate GL. The protective layer PF may include a polymer film.

The protective layer PF may include anti-fingerprint coating agent, hard coating agent, antistatic agent, etc. According to an aspect, a coating layer may be further included between a first adhesive layer AD1 and the base substrate GL.

The base substrate GL according to the inventive concept may have a form in which a portion overlapping the folding region FA is recessed. The recessed portion may have a form in which a portion is removed from a front surface of the base substrate GL along a third direction DR3 which is a thickness direction. Thus, a thickness of the base substrate GL in the folding region FA may be smaller than a thickness of the base substrate GL in non-folding regions NFA1 and NFA2. The recessed portion may be formed in an etching process. According to the inventive concept, the window WL with improved folding characteristics may be provided.

The lower film PM may protect a lower portion of the display panel DP. The lower film PM may include a flexible plastic material. For example, the lower film PM may include polyethylene terephthalate.

The support plate SP may be disposed on a lower side of the display panel DP. A portion of the support plate SP according to the inventive concept may be bent and absorb an impact applied between the housing HAU and components disposed on the support plate SP. In addition, the support plate SP may prevent foreign substances, etc., from being introduced into components disposed on the support plate SP.

The lower plate MP may be disposed on a lower portion of the support plate SP. The lower plate MP may include a plurality of holes HL penetrating the lower plate MP and overlapping the folding region so as to facilitate a folding operation of the electronic device ED. The lower plate MP may include metal. For example, the lower plate MP may include one of aluminum (Al) and molybdenum (Mo). However, aspects of the present disclosure are not limited thereto, and the lower plate MP may include a matrix including a filler and fiber lines, in a weave form, disposed inside the matrix. The fiber lines may be disposed in a fabric form inside the matrix.

The fiber lines may include a reinforced fiber composite. The reinforced fiber composite may be one of carbon fiber-reinforced plastic (CFRP) and glass fiber-reinforced plastic (GFRP). A diameter of one strand of fiber included in one fiber line may be about 3 um to about 10 um.

The matrix according to an aspect may include at least one of epoxy, polyester, polyamides, polycarbonates, polypropylene, polybutylene, or vinyl ester.

The matrix may include a filler. The filler may include at least one of silica, barium sulphate, sintered talc, barium titanate, titanium oxide, clay, alumina, mica, boehmite, zinc borate, or zinc stannate.

The electronic device ED according to an aspect may further include at least one among a cushion layer and a shielding layer. The cushion layer may prevent the lower plate MP from being pressed and plastic-deformed due to an external impact and force. The cushion layer may include elastomer such as a sponge, foam, or a urethane resin, etc. In addition, the cushion layer may be formed including at least one of an acrylic polymer, a urethane-based polymer, a silicon-based polymer, or an imide-based polymer. The shielding layer may be an electromagnetic wave shielding layer or a heat dissipation layer.

The electronic device ED according to an aspect may further include first to sixth adhesive layers AD1 to AD6. The first adhesive layer AD1 may be disposed between the base substrate GL and the protective layer PF. The second adhesive layer AD2 may be disposed between the optical layer RPL and the base substrate GL. The third adhesive layer AD3 may be disposed between the display module DM and the optical layer RPL. The fourth adhesive layer AD4 may be disposed between the lower film PM and the display module DM. The fifth adhesive layer AD5 may be disposed between the support plate SP and the lower film PM. The sixth adhesive layer AD6 may be disposed between the lower plate MP and the support plate SP.

The first to sixth adhesive layers AD1 to AD6 and adhesive layers to be described later may each include a typical adhesive such as a pressure sensitive adhesive (PSA), an optically clear adhesive (OCA), and an optical clear resin (OCR), and are not limited to any one aspect. In the electronic device ED according to an aspect, at least one of the first to sixth adhesive layers AD1 to AD6 may be omitted.

Referring to FIG. 4, the display module DM may include the display panel DP and the input sensing layer ISP disposed on the display panel DP. The display panel DP may be a component which substantially generates an image. The display panel DP may be an emissive display panel. For example, the display panel DP may be an organic light-emitting display panel, an inorganic light-emitting display panel, a micro-LED display panel, a micro-OLED display panel, or a nano-LED display panel.

The display panel DP may include a base layer BS, a circuit layer DP-CL, a display element layer DP-EL, and an encapsulation layer TFE which are sequentially stacked. Unlike the illustration, a functional layer may be further disposed between adjacent two layers among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate that is bendable, foldable, rollable, etc. The base layer BS may be a glass substrate, a metal substrate, a polymer substrate, or the like. However, aspects of the present disclosure are not limited thereto, and the base layer BS may include an inorganic layer, an organic layer, or a composite material layer.

The base layer BS may include a single layer or a multilayer. For example, the base layer BS may include a first synthetic resin layer, an inorganic layer which is a multilayer or a single layer, and a second synthetic resin layer disposed on the inorganic layer which is a multilayer or a single layer. The first synthetic resin layer and the second synthetic resin layer may each include a polyimide-based resin. In addition, the first synthetic resin layer and the second synthetic resin layer may each include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “~~based” resin refers to a resin including a functional group of “~~”.

The circuit layer DP-CL may be disposed on the base layer BS. The circuit layer DP-CL may include an insulating layer, a semiconductor pattern, a conductive pattern, a signal line, and the like. The display element layer DP-EL may be disposed on the circuit layer DP-CL. The display element layer DP-EL may include a light-emitting element (not shown). For example, the light-emitting element may include an organic light-emitting material, an inorganic light-emitting material, an organic-inorganic light-emitting material, quantum dots, quantum rods, a micro-LED, or a nano-LED.

The encapsulation layer TFE may be disposed on the display element layer DP-EL. The encapsulation layer TFE may protect the display element layer DP-EL from moisture, oxygen, and foreign substances such as dust particles. The encapsulation layer TFE may include at least one inorganic layer. For example, the encapsulation layer TFE may include an inorganic layer, an organic layer, and an inorganic layer which are sequentially stacked.

The input sensing layer ISP may be disposed on the display panel DP. The input sensing layer ISP may be directly disposed on the encapsulation layer TFE. Alternatively, an adhesive member may be disposed between the input sensing layer ISP and the display panel DP.

In this specification, one component being directly disposed on another component means that a third component is not disposed between the one component and the other component. That is, one component being “directly disposed” on another component means that the one component and the other component “are in contact with” each other.

The input sensing layer ISP may sense an external input, change the external input into a predetermined input signal, and provide the input signal to the display panel DP. For example, the input sensing layer ISP may be a touch sensing layer which senses a touch. The input sensing layer ISP may recognize a direct touch of a user, an indirect touch of a user, a direct touch of an object, an indirect touch of an object, or the like.

The input sensing layer ISP may sense at least one among a position and intensity (pressure) of a touch applied from the outside. The input sensing layer ISP may have various structures or include various materials and is not limited to any one aspect. For example, the input sensing layer ISP may sense an external input in a capacitive manner. The display panel DP may be provided with an input signal from the input sensing layer ISP and generate an image corresponding to the input signal.

FIG. 5 is a cross-sectional view of a window according to an aspect of the present disclosure. FIG. 5 illustrates only the window WL and the optical layer RPL disposed on a lower portion of the window WL described with reference to FIG. 3. The window WL and the optical layer RPL may be coupled by the second adhesive layer AD2.

The window WL according to an aspect may include the protective layer PF and the base substrate GL. The protective layer PF and the base substrate GL may be coupled by the first adhesive layer AD1. According to the present aspect, an upper surface G-U of the base substrate GL may be in contact with the first adhesive layer AD1, and a lower surface G-B of the base substrate GL may be in contact with the second adhesive layer AD2. The upper surface G-U of the base substrate GL may face each other in an in-folded state.

The base substrate GL may include a first non-folding portion FG1 overlapping a first non-folding region NFA1, a second non-folding portion FG2 overlapping a second non-folding region NFA2, and a folding portion FM overlapping the folding region FA. The first non-folding portion FG1 and the second non-folding portion FG2 may be spaced apart along a second direction DR2 with the folding portion FM therebetween in a state in which the base substrate GL is unfolded.

The folding portion FM may include a region recessed in a direction from the protective layer PF toward the base substrate GL. According to the present aspect, the folding portion FM may include a flat portion CM and first and second inclined portions SG1 and SG2.

The first inclined portion SG1 may extend from the first non-folding portion FG1 and may be connected to one end of the flat portion CM. The second inclined portion SG2 may extend from the second non-folding portion FG2 and may be connected to the other end of the flat portion CM.

In a cross-sectional view, the first inclined portion SG1 and the second inclined portion SG2 may each be inclined at a predetermined angle. For example, the first inclined portion SG1 may extend from the first non-folding portion FG1 to the flat portion CM, and in a state in which the base substrate GL is unfolded, the first inclined portion SG1 may be inclined downwardly from the first non-folding portion FG1 toward the flat portion CM.

The second inclined portion SG2 may extend from the second non-folding portion FG2 to the flat portion CM, and in a state in which the base substrate GL is unfolded, the second inclined portion SG2 may be inclined downwardly from the second non-folding portion FG2 toward the flat portion CM.

According to the present aspect, the first inclined portion SG1 and the second inclined portion SG2 may have a linear shape in a state in which the base substrate GL is unfolded.

According to an aspect, a first thickness TH1 of the first and second non-folding portions FG1 and FG2 may be greater than a second thickness TH2 of the flat portion CM. For example, the first thickness TH1 may be about 50 um to about 300 um. The second thickness TH2 may be about 20 um to about 100 um.

In a state in which the base substrate GL is unfolded, a first width WD1 of the flat portion CM in the second direction DR2 may be greater than a second width WD2 of each of the first and second inclined portions SG1 and SG2. For example, the first width WD1 may be about 5 mm to about 50 mm. The second width WD2 may be about 1 mm to about 20 mm.

According to the present aspect, an external angle Θ1 between an imaginary line extending in a first direction DR1 along the flat portion CM and each of the first and second inclined portions SG1 and SG2 may be about 0.01 degrees to about 1 degree. Angles between imaginary lines extending in the first direction DR1 along the first and second non-folding portions FG1 and FG2 and the first and second inclined portions SG1 and SG2 may be the same as or smaller than the external angle Θ1.

According to the present aspect, the folding portion FM in which a portion of the base substrate GL overlapping the folding region FA is recessed may be included, and thus a defect in which a crack occurs in a region overlapping the folding region FA of the window WL during a folding operation of the electronic device may be prevented. Accordingly, the electronic device ED including the window WL with improved impact resistance and folding characteristics may be provided.

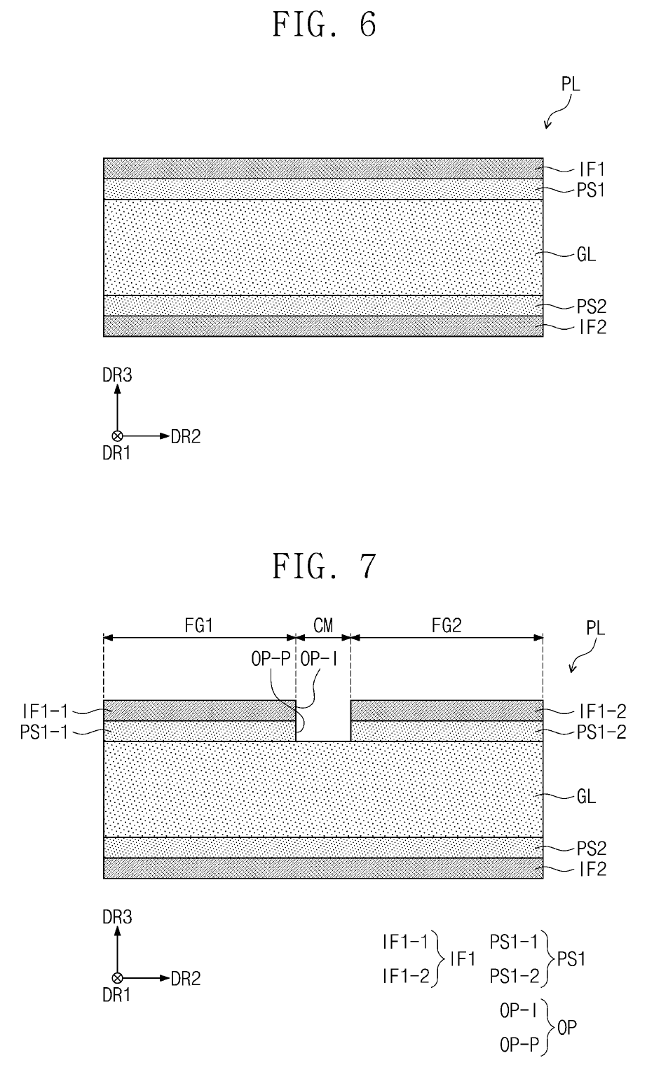

FIGS. 6 to 11B are diagrams illustrating sequential steps of a method for manufacturing a window according to an aspect of the present disclosure. Components that are the same as or similar to the components described with reference to FIGS. 1A to 5 will be denoted as the same or similar reference numerals or symbols, and duplicate content is not provided. Hereinafter, a method for manufacturing the window described with reference to FIG. 5 will be described with reference to FIGS. 6 to 11B.

Referring to FIG. 6, a method for manufacturing a window according to an aspect may include providing a preliminary substrate PL. The preliminary substrate PL may include a base substrate GL, a first adhesive layer PS1, a second adhesive layer PS2, a first protective film IF1, and a second protective film IF2.

The base substrate GL may be a target substrate on which an etching process is performed. The base substrate GL may include an optically transparent insulating material. For example, the base substrate GL may include glass. Thus, an etching process in which the base substrate GL is formed may have isotropic etching characteristics.

The first adhesive layer PS1 may be disposed on an upper surface of the base substrate GL. The first adhesive layer PS1 may couple the first protective film IF1 and the base substrate GL. According to aspects of the present disclosure, the first adhesive layer PS1 disposed on the upper surface of the base substrate GL on which an etching process is performed may be a UV photosensitive adhesive layer. For example, the first adhesive layer PS1 may be a UV photosensitive pressure sensitive adhesive (PSA). Thus, when the preliminary substrate PL is irradiated with UV, adhesive force of the first adhesive layer PS1 may be reduced, and the first adhesive layer PS1 may be separated from the upper surface of the base substrate GL.

The second adhesive layer PS2 may be disposed on a lower surface of the base substrate GL. The second adhesive layer PS2 may couple the second protective film IF2 and the base substrate GL. According to aspects of the present disclosure, the second adhesive layer PS2 disposed on the lower surface of the base substrate GL which is irradiated with UV may be a thermal pressure sensitive adhesive (PSA) which exhibits adhesive characteristics due to heat. Thus, even if the preliminary substrate PL is irradiated with UV, the second adhesive layer PS2 may be attached to the lower surface of the base substrate GL since the adhesive characteristics of the second adhesive layer PS2 are exhibited.

The first protective film IF1 may be attached to the upper surface of the base substrate GL through the first adhesive layer PS1. According to the present aspect, the first protective film IF1 may be a film manufactured to be easily removable and acid-resistant. The first protective film IF1 may include at least one of polyolefin (PO), polyethylene (PE), polyethylene terephthalate (PET), or polyvinyl chloride (PVC). As the first protective film IF1 is acid-resistant, an etching process may be easily performed on a region, on which the first protective film IF1 is not disposed, of the base substrate GL, and a region, on which the first protective film IF1 is disposed, of the base substrate GL may not be etched since the first protective film IF1 functions as a mask.

The first protective film IF1 may be attached to the upper surface of the base substrate GL through the first adhesive layer PS1. According to the present aspect, the first protective film IF1 may be a film manufactured to be easily removable and acid-resistant. The first protective film IF1 may include at least one of polyolefin (PO), polyethylene (PE), polyethylene terephthalate (PET), or polyvinyl chloride (PVC). According to an aspect, a thickness of the first protective film IF1 may be about 50 um to about 200 um.

As the first protective film IF1 is acid-resistant, an etching process may be easily performed on a region, on which the first protective film IF1 is not disposed, of the base substrate GL, and a region, on which the first protective film IF1 is disposed, of the base substrate GL may not be etched since the first protective film IF1 functions as a mask.

The second protective film IF2 may be attached to the lower surface of the base substrate GL through the second adhesive layer PS2. According to the present disclosure, the second protective film IF2 may be a film manufactured to be easily removable and acid-resistant. The second protective film IF2 may include at least one of polyolefin (PO), polyethylene (PE), polyethylene terephthalate (PET), or polyvinyl chloride (PVC). According to an aspect, the second protective film IF2 may be attached to the lower surface of the base substrate GL on which an etching process is performed. According to an aspect, a thickness of the second protective film IF2 may be about 50 um to about 200 um.

Thereafter, referring to FIG. 7, a method for manufacturing a window according to an aspect may include forming an opening OP in the preliminary substrate PL. The opening OP may include a first opening OP-P and a second opening OP-I.

The first opening OP-P may be formed by removing the first adhesive layer PS1 overlapping a flat portion CM of the base substrate GL. The flat portion CM may correspond to the flat portion CM of the window WL described with reference to FIG. 5. The second opening OP-I may be formed by removing the first protective film IF1 overlapping the first opening OP-P.

As the first opening OP-P is formed, a first adhesive portion PS1-1 overlapping a first non-folding portion FG1 of the base substrate GL and a second adhesive portion PS1-2 overlapping a second non-folding portion FG2 of the base substrate GL may be formed in the first adhesive layer PS1.

In addition, as the second opening OP-I is formed, a first film portion IF1-1 overlapping the first adhesive portion PS1-1 and a second film portion IF1-2 overlapping the second adhesive portion PS1-2 may be formed in the first protective film IF1.

According to an aspect, the providing of the preliminary substrate PL described with reference to FIG. 6 may be provided in a state in which the first opening OP-P is formed in the first adhesive layer PS1 and the second opening OP-I is formed in the first protective film IF1, and is not limited to any one aspect.

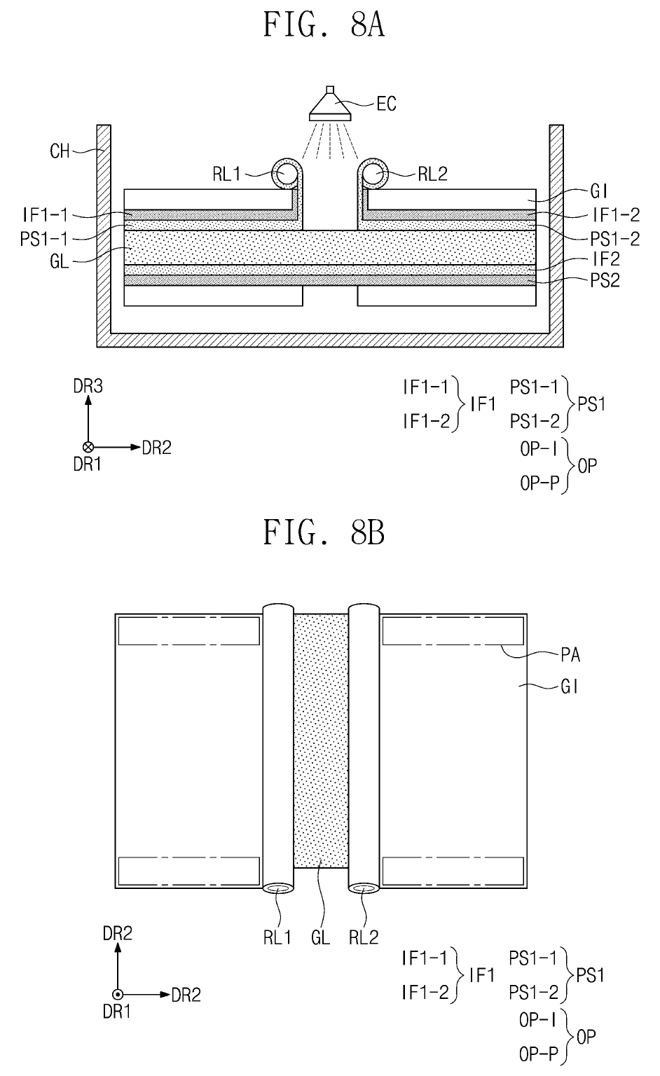

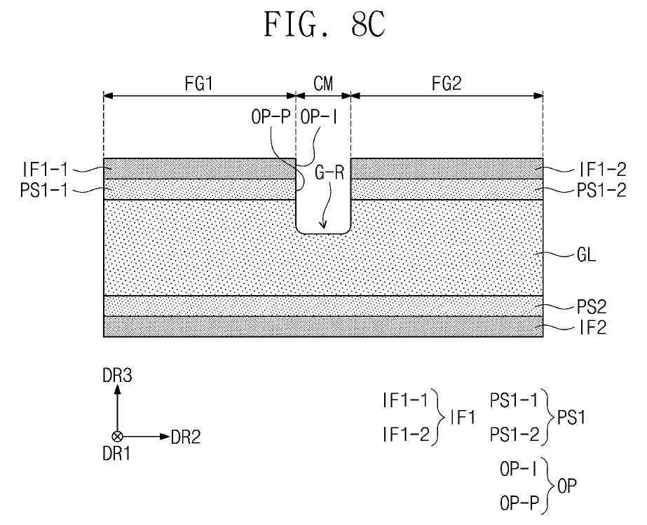

Thereafter, referring to FIGS. 8A to 8C, a method for manufacturing a window according to an aspect may include forming a recess G-R by etching the base substrate GL. In this step, a portion corresponding to the flat portion CM of the window WL described with reference to FIG. 5 may be manufactured in advance by forming the recess G-R in the base substrate GL. That is, a thin portion of the base substrate GL may be formed first.

A process of forming the recess G-R in the base substrate GL may be performed inside a chamber CH. The chamber CH may include first and second rollers RL1 and RL2 and a spray EC which sprays an etchant.

In this step, an end of each of the first film portion IF1-1 and the first adhesive portion PS1-1 may be rolled on the first roller RL1. In addition, an end of each of a second film portion IF1-2 and the second adhesive portion PS1-2 may be rolled on the second roller RL2.

As illustrated in FIG. 8B, the first and second rollers RL1 and RL2 may be moved in directions from a center of the base substrate GL to outer sides of the base substrate GL while winding the adhesive portions PS1-1 and PS1-2 and the film portions IF1-1 and IF1-2 by rotation in a subsequent process.

The preliminary substrate PL may be surrounded by a guide portion GI during a process of forming the recess G-R in the chamber CH.

The guide portion GI may be provided such that a first region, to which an etchant is sprayed, of the upper surface of the base substrate GL and a second region, which is opposed to the first region, of the lower surface of the base substrate GL are open.

As illustrated in FIG. 8B, the guide portion GI may be in contact with the preliminary substrate PL at ends, of the guide portion GI, spaced apart along a second direction DR2 and cover one side of the preliminary substrate PL. On the other hand, ends, of the guide portion GI, spaced apart along a second direction DR2 in which the recess G-R extends may expose the other side of the preliminary substrate PL.

This is for easily exposing a region, to which the etchant is sprayed, of the upper surface of the base substrate GL and a region, which is irradiated with UV, of the lower surface of the base substrate GL along with movement of the first and second rollers RL1 and RL2 when the first and second rollers RL1 and RL2 are moved in directions from the center of the base substrate GL to the outer sides of the base substrate GL while winding the adhesive portions PS1-1 and PS1-2 and the film portions IF1-1 and IF1-2 by rotation.

Referring to FIG. 8C, forming the recess G-R by spraying the etchant to a region corresponding to the flat portion CM of the window WL described with reference to FIG. 5 may be included. The etchant may pass through the opening OP and may be sprayed to the upper surface, of the base substrate GL, exposed from the first adhesive layer PS1 and the first protective film IF1 due to the opening OP. The recess G-R may be formed at a portion to which the etchant is sprayed.

The recess G-R may be formed by removing a portion of the base substrate GL in a direction from the upper surface to the lower surface of the base substrate GL. Forming the recess G-R may be a process of forming a portion corresponding to the flat portion CM of the window WL described with reference to FIG. 5 in advance.

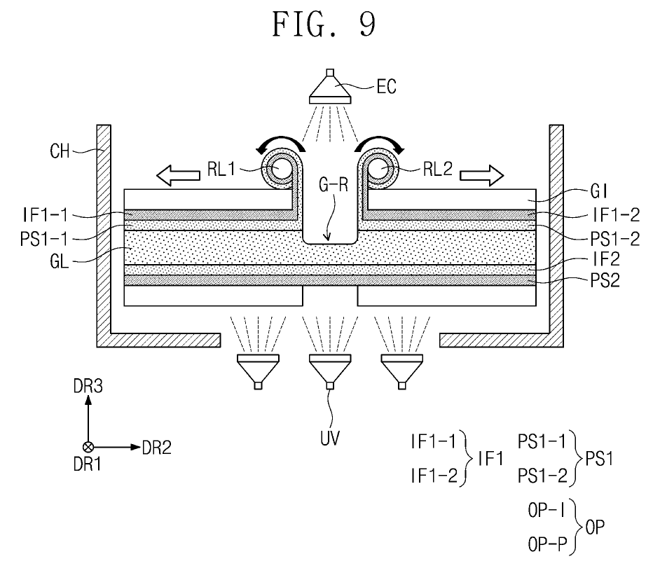

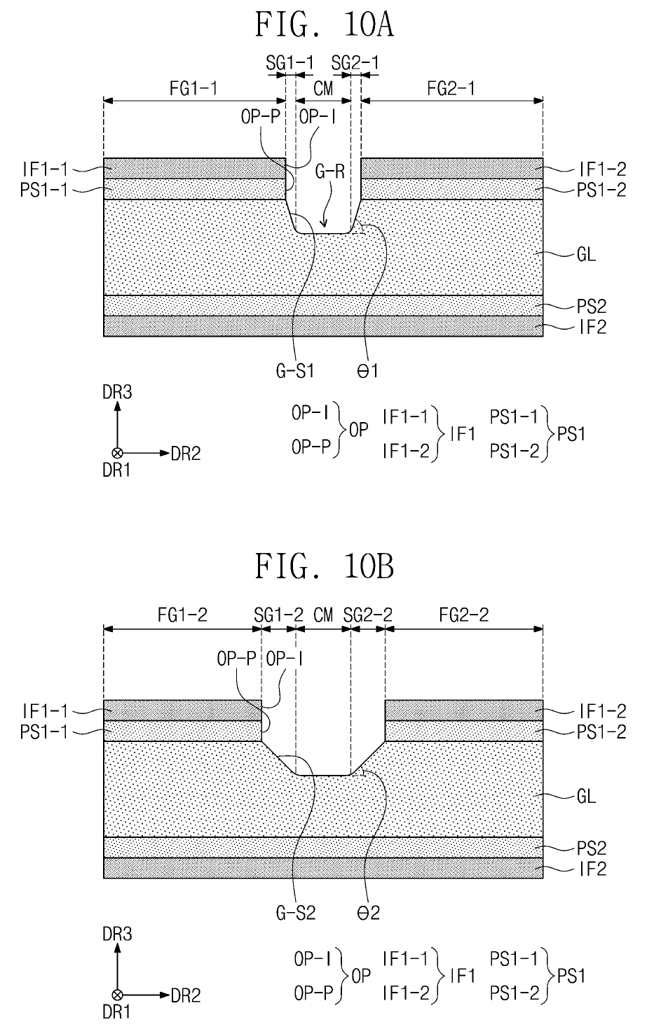

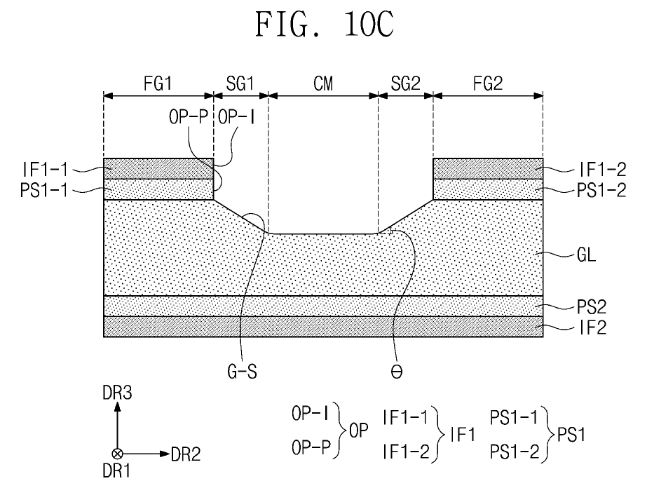

Thereafter, referring to FIGS. 9 to 10C, a method for manufacturing a window according to an aspect may include forming inclined portions in the base substrate GL.

Referring to FIG. 9, the forming of the inclined portions may include irradiating a rear surface of the base substrate GL with UV by using a UV device UV. A region, which overlaps the recess G-R, of the base substrate GL may be irradiated with the UV device UV.

The first adhesive layer PS1 disposed on the upper surface of the base substrate GL and the second adhesive layer PS2 disposed on the lower surface of the base substrate GL may include pressure sensitive adhesives (PSAs) having different characteristics. According to aspects of the present disclosure, the first adhesive layer PS1 may be a UV photosensitive pressure sensitive adhesive. Thus, when the preliminary substrate PL is irradiated with UV, adhesive force of the first adhesive layer PS1 may be reduced, and the first adhesive layer PS1 may be separated from the upper surface of the base substrate GL.

The second adhesive layer PS2 disposed on the lower surface of the base substrate GL may be a thermal pressure sensitive adhesive which exhibits adhesive characteristics due to heat. Thus, even if the preliminary substrate PL is irradiated with UV, the second adhesive layer PS2 may be attached to the lower surface of the base substrate GL since the adhesive characteristics of the second adhesive layer PS2 are exhibited.

When the rear surface of the base substrate GL is irradiated with UV by using the UV device UV, adhesive force of the first adhesive portion PS1-1 and the second adhesive portion PS1-2 adjacent to the recess G-R may be reduced or lost, and thus the first adhesive portion PS1-1 and the second adhesive portion PS1-2 adjacent to the recess G-R may be separated from the upper surface of the base substrate GL adjacent to the recess G-R. Thus, the first film portion IF1-1 and the second film portion IF1-2 disposed on a portion of which adhesive force is reduced or lost may also be easily separated from the base substrate GL.

In this case, the first and second rollers RL1 and RL2 may be moved in directions from the center of the base substrate GL to the outer sides of the base substrate GL while winding the adhesive portions PS1-1 and PS1-2 and the film portions IF1-1 and IF1-2 by rotating the first and second rollers RL1 and RL2.

In this case, the guide portion GI may be moved from the base substrate GL while exposing the base substrate GL in association with movement of the first and second rollers RL1 and RL2.

FIGS. 10A to 10C illustrate inclined portions SG1 and SG2 which are formed in the base substrate GL since the first roller RL1 and the second roller RL2 open the upper surface of the base substrate GL from the adhesive portions PS1-1 and PS1-2 and the film portions IF1-1 and IF1-2 in chronological order.

FIGS. 10A to 10C illustrate the inclined portions SG1 and SG2 which are formed through three steps, but this is for convenience of description, and forming the inclined portions SG1 and SG2 in the base substrate GL may be formed in a continuous process. Thus, primary to tertiary processes to be described later may be performed as a continuous process.

As illustrated in FIGS. 10A to 10C, the inclined portions SG1 and SG2 may be formed from both ends of the recess G-R of the base substrate GL according to moving speed of the first and second rollers RL1 and RL2. Thus, according to aspects of the present disclosure, moving the first and second rollers RL1 and RL2 and forming the inclined portions SG1 and SG2 in the base substrate GL may be simultaneously performed.

Primary inclined portions SG1-1 and SG2-1 may be formed in the base substrate GL in the primary process. The primary inclined portions SG1-1 and SG2-1 may correspond to first side surfaces G-S1, of the base substrate GL, extending from the upper surface of the base substrate GL defining the recess G-R to primary non-folding portions FG1-1 and FG2-1.

An angle between the first side surface G-S1 and an imaginary line extending from the upper surface of the base substrate GL defining the recess G-R may be defined as a first preliminary angle Θ1.

Secondary inclined portions SG1-2 and SG2-2 may be formed in the base substrate GL in the secondary process. The secondary inclined portions SG1-2 and SG2-2 may correspond to second side surfaces G-S2, of the base substrate GL, extending from the upper surface of the base substrate GL defining the recess G-R to secondary non-folding portions FG1-2 and FG2-2.

An angle between the second side surface G-S2 and an imaginary line extending from the upper surface of the base substrate GL defining the recess G-R may be defined as a second preliminary angle Θ2.

The second preliminary angle Θ2 may be smaller than the first preliminary angle Θ1. In addition, in a second direction DR2, widths of the secondary inclined portions SG1-2 and SG2-2 may be greater than widths of the primary inclined portions SG1-1 and SG2-1. Thus, in the second direction DR2, widths of the secondary non-folding portions FG1-2 and FG2-2 may be smaller than widths of the primary non-folding portions FG1-1 and FG2-1.

The inclined portions SG1 and SG2 may be formed in the base substrate GL in the tertiary process in which an etching process ends. The inclined portions SG1 and SG2 may correspond to side surfaces G-S, of the base substrate GL, extending from the upper surface of the base substrate GL defining the recess G-R to non-folding portions FG1 and FG2.

An angle between the side surface G-S and an imaginary line extending from the upper surface of the base substrate GL defining the recess G-R may be defined as an external angle Θ1.

The external angle Θ1 may be smaller than the second preliminary angle Θ2. In addition, in the second direction DR2, widths of the inclined portions SG1 and SG2 may be greater than widths of the secondary inclined portions SG1-2 and SG2-2. Thus, in the second direction DR2, widths of the non-folding portions FG1 and FG2 may be smaller than widths of the secondary non-folding portions FG1-2 and FG2-2. According to an aspect, the external angle Θ1 may be about 0.01 degrees to about 1 degree.

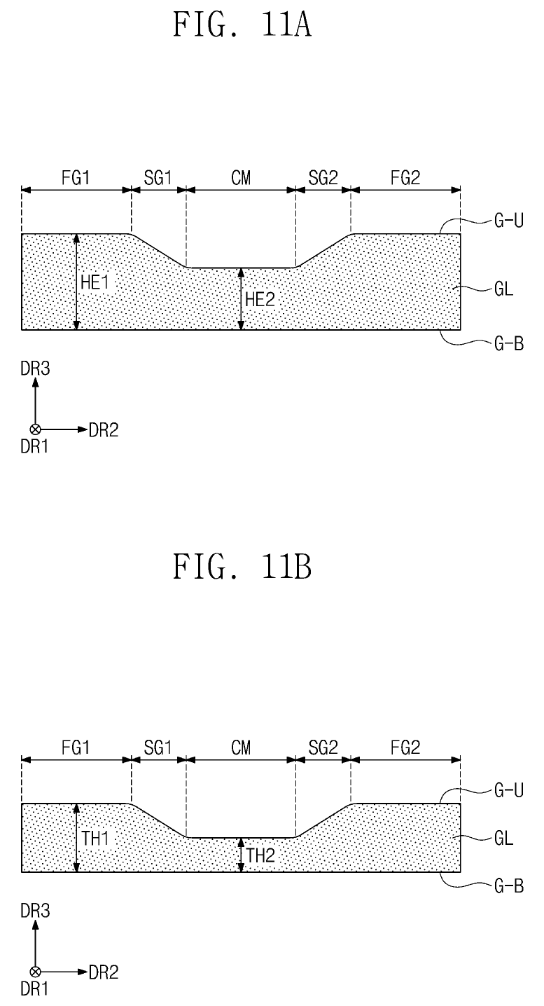

Thereafter, referring to FIG. 11A, removing the adhesive layers PS1 and PS2 and the protective films IF1 and IF2 from the base substrate GL may be included.

When the etching process is completed, a flat portion CM, first and second non-folding portions FG1 and FG2, a first inclined portion SG1 connecting one end of the flat portion CM and the first non-folding portion FG1, and a second inclined portion SG2 connecting the other end of the flat portion CM and the second non-folding portion FG2 may be formed in the base substrate GL in which the adhesive layers PS1 and PS2 and the protective films IF1 and IF2 are removed.

In this case, the flat portion CM of the base substrate GL may have a second preliminary thickness HE2, and the first and second non-folding portions FG1 and FG2 of the base substrate GL may have a first preliminary thickness HE12.

Thereafter, referring to FIG. 11B, etching the upper surface and the lower surface of the base substrate GL may be included. A target thickness may be achieved through blanket etching the base substrate GL. At the same time, a boundary of a discontinuity which is formed at the base substrate GL may become less distinct.

According to an aspect, after the blanket etching is performed, the flat portion CM may have a second thickness TH2 which is smaller than the second preliminary thickness HE2, and the first and second non-folding portions FG1 and FG2 may have a first thickness TH1 which is smaller than the first preliminary thickness HE1. For example, the first thickness TH1 may be about 50 um to about 300 um. The second thickness TH2 may be about 20 um to about 100 um. Lengths and angles of the inclined portions SG1 and SG2 may be determined according to moving speed of the rollers RL1 and RL2. For example, when moving speed of the rollers RL1 and RL2 is set to be high, the inclined portions SG1 and SG2 may be steeply formed, and when moving speed of the rollers RL1 and RL2 is set to be low, the inclined portions SG1 and SG2 may be slowly formed.

However, aspects of the present disclosure are not limited thereto. That is, in the providing of the preliminary substrate PL described with reference to FIG. 6, the base substrate GL may be provided in a state in which the base substrate GL is processed to have a target thickness. In this case, a process of blanket etching the base substrate GL may be skipped in a last subsequent process and is not limited to any one aspect.

According to aspects of the present disclosure, a region, which is etched, of the base substrate GL may be exposed by moving the rollers RL1 and RL2, and thus it may be possible to resolve an issue of occurrence of a discontinuity at points at which the flat portion CM and the inclined portions SG1 and SG2 are connected or at the inclined portions SG1 and SG2. Accordingly, a method for manufacturing a window that alleviates a defect in which a discontinuity is viewed by a user may be provided. In addition, according to aspects of the present disclosure, the inclined portions SG1 and SG2 of the base substrate GL may be formed by controlling moving speed and time of the rollers RL1 and RL2, and thus a method for manufacturing a window, which may reduce process cost and time compared to those of performing an etching process through physical detachment of a film used for forming a window of the existing foldable electronic device, may be provided.

According to aspects of the present disclosure, since a folding portion in which a portion of a base substrate overlapping a folding region of a window is recessed is included, a crack of the window may be prevented from occurring during a folding operation of an electronic device. Accordingly, a method for manufacturing a window with improved impact resistance and folding characteristics may be provided.

In addition, since an etching process is performed using a roller, a discontinuity may be removed, and thus a method for manufacturing a window with improved visibility may be provided.

In the above, description has been made with reference to aspects of the present disclosure, but those skilled or of ordinary skill in the art may understand that various modifications and changes may be made to the described aspects of the present disclosure insofar as such modifications and changes do not depart from the spirit and technical scope of the present disclosure set forth in the claims to be described later.

Therefore, the technical scope of the present disclosure is not to be limited to the contents stated in the detailed description of the specification, but should be determined by the claims.

What is claimed is:

1. A method for manufacturing a window, the method comprising:
providing a preliminary substrate comprising a base substrate a first adhesive layer, a first protective film, a second adhesive layer, and a second protective film, wherein the first adhesive layer and the first protective film are disposed on an upper surface of the base substrate, and the second adhesive layer and the second protective film are disposed on a lower surface of the base substrate;
forming an opening by removing a portion of the first adhesive layer and a portion of the first protective film so that a first portion of the upper surface of the base substrate is exposed;
surrounding at least a portion of the preliminary substrate with a guide portion;
forming a recess in the upper surface of the base substrate by etching the first portion of the upper surface of the base substrate;
irradiating the lower surface of the base substrate with ultraviolet (UV) radiation;
gradually removing the first adhesive layer and the first protective film from a second portion of the upper surface of the base substrate using a roller disposed on the preliminary substrate; and
forming inclined portions in the base substrate by etching the second portion of the upper surface of the base substrate, from which the first adhesive layer and the first protective film are removed,
wherein the gradually removing of the first adhesive layer and the first protective film and the forming of the inclined portions are simultaneously performed.

2. The method of claim 1, wherein an external angle between a line parallel to an upper surface of the recess and side surfaces of the inclined portions of the base substrate increases as the roller is moved faster.

3. The method of claim 2, wherein the external angle is from about 0.01 degrees to about 1 degree.

4. The method of claim 1, further comprising removing the guide portion from the preliminary substrate after the forming of the inclined portions.

5. The method of claim 4, further comprising removing the first and second adhesive layers and the first and second protective films from the base substrate.

6. The method of claim 5, further comprising blanket etching the upper surface and the lower surface of the base substrate after the removing of the first and second adhesive layers and the first and second protective films from the base substrate.

7. The method of claim 6, wherein the base substrate comprises inclined portions, a flat portion disposed between the inclined portions, and non-folding portions connected to respective ends of the inclined portions after the blanket etching.

8. The method of claim 7, wherein a thickness of the non-folding portions of the base substrate is greater than a thickness of the flat portion of the base substrate.

9. The method of claim 8, wherein the thickness of the non-folding portions of the base substrate is from about 50 um to about 300 um, and
the thickness of the flat portion of the base substrate is from about 20 um to about 100 um.

10. The method of claim 1, wherein the base substrate comprises glass.

11. The method of claim 1, wherein the first adhesive layer comprises a first pressure sensitive adhesive and the second adhesive layer comprise a second pressure sensitive adhesive, wherein the first pressure sensitive adhesive and the second pressure sensitive adhesive have different characteristics.

12. The method of claim 11, wherein the first adhesive layer comprises a UV photosensitive pressure sensitive adhesive, and
the second adhesive layer comprises a thermal pressure sensitive adhesive.

13. The method of claim 1, wherein the first protective film and the second protective film each comprise at least one of polyolefin (PO), polyethylene (PE), polyethylene terephthalate (PET), or polyvinyl chloride (PVC).

14. The method of claim 1, wherein after the forming of the recess,
the first adhesive layer is divided into a first adhesive portion and a second adhesive portion spaced apart from each other with the recess therebetween, and
the first protective film is divided into a first film portion disposed on the first adhesive portion and a second film portion disposed on the second adhesive portion, the first film portion and the second film portion being spaced apart from each other with the recess therebetween.

15. The method of claim 1, wherein the roller comprises a first roller disposed on the first film portion and a second roller disposed on the second film portion,
an end of the first film portion and an end of the first adhesive portion adjacent to the recess are wound by the first roller, and
an end of the second film portion and an end of the second adhesive portion adjacent to the recess are wound by the second roller.

16. The method of claim 15, wherein in the gradually removing of the first adhesive layer and the first protective film,
the first roller and the second roller gradually move away from each other from a center of the base substrate to outer sides of the base substrate.

17. The method of claim 16, wherein in the gradually removing of the first adhesive layer and the first protective film,
as the first roller and the second roller move away from each other,
the base substrate is gradually exposed while the first adhesive layer and the first film portion are being wound on the first roller due to lost adhesive force of the first adhesive layer irradiated with the UV radiation, and
the base substrate is gradually exposed while the second adhesive layer and the secondfilm portion are being wound on the second roller due to lost adhesive force of the second adhesive layer irradiated with the UV radiation.

18. The method of claim 16, wherein when the first roller and the second roller move away from each other, the guide portion is moved to expose the base substrate.

19. The method of claim 1, wherein the guide portion exposes an upper surface and a lower surface of the base substrate overlapping the recess.

20. The method of claim 19, wherein the guide portion covers a side of the base substrate extending in a first direction that intersects a second direction in which the upper surface of the guide portion extends.
